(19) United States
(12) Patent Application Publication
(10) Pub. No.: US 2025/0174557 A1
(43) Pub. Date: May 29, 2025

(54) SEMICONDUCTOR DIE HAVING A DIE DAMAGE RING AND FABRICATION METHOD THEREOF

(71) Applicant: MEDIATEK INC., Hsinchu City (TW)

(72) Inventors: Cing-Yao Jhan, Hsinchu City (TW); Tien-Yu LU, Hsinchu City (TW); Chien-Kai Huang, Hsinchu City (TW); Ting-Chen Shih, Hsinchu City (TW); Chu-Wei Hu, Hsinchu City (TW)

(73) Assignee: MEDIATEK INC., Hsinchu City (TW)

(21) Appl. No.: 18/954,424

(22) Filed: Nov. 20, 2024

Related U.S. Application Data
(60) Provisional application No. 63/603,689, filed on Nov. 29, 2023.

(51) Int. Cl. H01L 23/528; H01L 21/768; H01L 23/00; H01L 23/522

(52) U.S. Cl. CPC H01L 23/5283; H01L 21/76898; H01L 23/5226; H01L 23/562

(57) ABSTRACT

A semiconductor die includes a substrate comprising an integrated circuit region thereon, a front end of line (FEOL) portion disposed on a front side of the substrate, a back end of line (BEOL) portion disposed on the FEOL portion, a power delivery network (PDN) portion disposed on a back side of the substrate, and a plurality of through substrate vias penetrating through the substrate and disposed along a perimeter of the integrated circuit region. The BEOL portion includes a first discontinuous ring disposed along the perimeter of the integrated circuit region. The PDN portion includes a second discontinuous ring disposed along the perimeter of the integrated circuit region. The first discontinuous ring is interlaced with the second discontinuous ring through the plurality of through substrate vias, thereby constituting a die damage ring.

### CROSS REFERENCE TO RELATED APPLICATIONS

This application claims the benefit of U.S. Provisional Application No. 63/603,689, filed on Nov. 29, 2023. The content of the application is incorporated herein by reference.

### BACKGROUND

The present disclosure relates generally to the field of semiconductor technology. More specifically, the present disclosure relates to a semiconductor die having an interlaced die damage ring and a method for manufacturing the same.

As known in the art, semiconductor die edge is susceptible to manufacturing defects such as die chipping or cracking. The die chipping or cracking at die edges may be caused by, for example, wafer sawing, die handling or test. To detect failures or defects including those caused by cracks near the die edges, an edge die monitor (EDM) or defect detection structure is typically provided around the periphery of the die.

There is a need in this industry to provide an improved chip device having a die damage ring for detection of damages to the semiconductor die.

### SUMMARY

It is one object of the present disclosure to provide an improved semiconductor die having an interlaced die damage ring and a method for manufacturing the same in order to solve the prior art deficiencies or shortcomings.

One aspect of the disclosure provides a semiconductor die including a substrate comprising an integrated circuit region thereon, a front end of line (FEOL) portion disposed on a front side of the substrate, a back end of line (BEOL) portion disposed on the FEOL portion, a power delivery network (PDN) portion disposed on a back side of the substrate, and a plurality of through substrate vias penetrating through the substrate and disposed along a perimeter of the integrated circuit region. The BEOL portion includes a first discontinuous ring disposed along the perimeter of the integrated circuit region. The PDN portion includes a second discontinuous ring disposed along the perimeter of the integrated circuit region. The first discontinuous ring is interlaced with the second discontinuous ring through the plurality of through substrate vias, thereby constituting a die damage ring.

According to some embodiments, the first discontinuous ring comprises a plurality of first interconnect blocks arranged intermittently along the perimeter of the integrated circuit region.

According to some embodiments, the plurality of first interconnect blocks comprises a plurality of duplicate first interconnect structures arranged at regular intervals along the perimeter of the integrated circuit region.

According to some embodiments, the second discontinuous ring comprises a plurality of second interconnect blocks arranged intermittently along the perimeter of the integrated circuit region.

According to some embodiments, the plurality of second interconnect blocks comprises a plurality of duplicate second interconnect structures arranged at regular intervals along the perimeter of the integrated circuit region.

According to some embodiments, the plurality of first interconnect blocks and the plurality of second interconnect blocks are arranged alternately along the perimeter of the integrated circuit region.

According to some embodiments, the plurality of first interconnect blocks comprises a plurality of top metal layers, and wherein the plurality of through substrate vias is directly connected to the plurality of top metal layers, respectively.

According to some embodiments, the plurality of first interconnect blocks comprises a plurality of bottom metal layers, and wherein the plurality of through substrate vias is directly connected to the plurality of bottom metal layers, respectively.

According to some embodiments, the PDN portion comprises a plurality of buried rails, and wherein the plurality of through substrate vias is directly connected to the plurality of buried rails, respectively.

According to some embodiments, the front end of line (FEOL) portion comprises a plurality of active circuit elements.

According to some embodiments, the plurality of active circuit elements comprises a plurality of source/drain regions, and wherein the plurality of through substrate vias is directly connected to the plurality of source/drain regions, respectively.

According to some embodiments, the front end of line (FEOL) portion comprises a plurality of backside contacts is connected to the plurality of active circuit elements, respectively, and wherein the plurality of through substrate vias is directly connected to the plurality of backside contacts, respectively.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 illustrates an exemplary semiconductor die having a die damage ring;

FIG. 2 is a schematic, perspective diagram of the exemplary semiconductor die in FIG. 1;

FIG. 3 is an enlarged, schematic diagram showing a portion of the die damage ring in FIG. 2 according to an embodiment of the invention;

FIG. 4 is an enlarged, schematic diagram showing a portion of the die damage ring in FIG. 2 according to another embodiment of the invention;

FIG. 5 is an enlarged, schematic diagram showing a portion of the die damage ring in FIG. 2 according to still another embodiment of the invention;

FIG. 6 is an enlarged, schematic diagram showing a portion of the die damage ring in FIG. 2 according to yet another embodiment of the invention;

FIG. 7 is an enlarged, schematic diagram showing a portion of the die damage ring in FIG. 2 according to yet another embodiment of the invention; and

FIG. 8 to FIG. 10 are schematic diagrams showing an exemplary method for forming a semiconductor die according to one embodiment of the invention.

### DETAILED DESCRIPTION

In the following detailed description of embodiments of the invention, reference is made to the accompanying drawings, which form a part hereof, and in which is shown by way of illustration specific preferred embodiments in which the disclosure may be practiced.

These embodiments are described in sufficient detail to enable those skilled in the art to practice them, and it is to be understood that other embodiments may be utilized and that mechanical, chemical, electrical, and procedural changes may be made without departing from the spirit and scope of the present disclosure. The following detailed description is, therefore, not to be taken in a limiting sense, and the scope of embodiments of the present invention is defined only by the appended claims.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items. The term “dummy die”, which is a non-function die, is referred to as a semiconductor die or chip that does not have any electrical function.

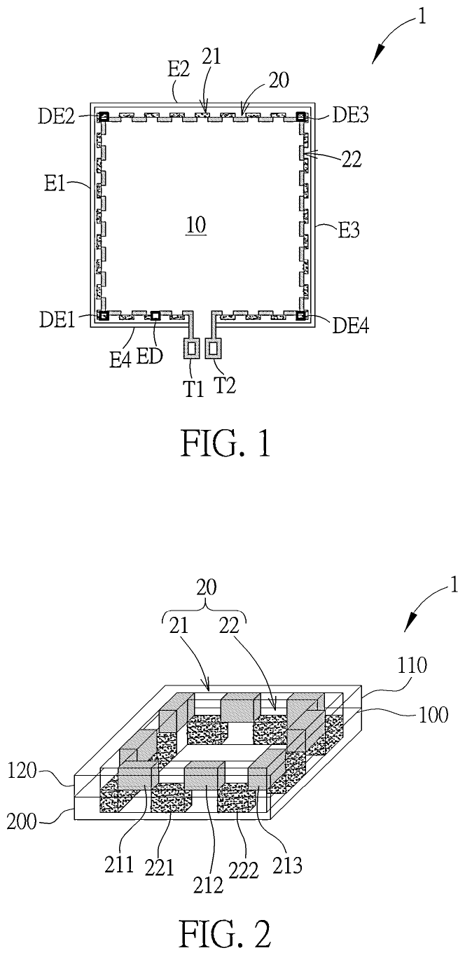

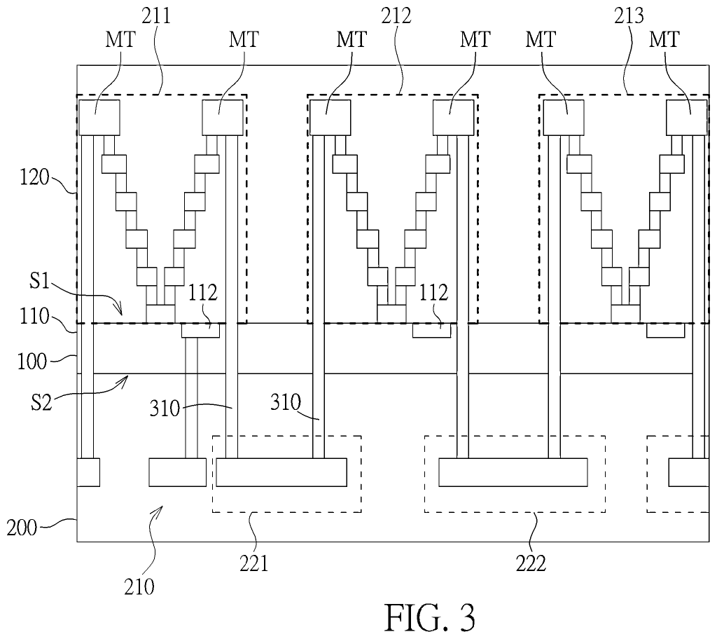

Please refer to FIG. 1 to FIG. 3. FIG. 1 illustrates an exemplary semiconductor die having a die damage ring. FIG. 2 is a schematic, perspective diagram of the exemplary semiconductor die in FIG. 1. FIG. 3 is an enlarged, schematic diagram showing a portion of the die damage ring in FIG. 2 according to an embodiment of the invention.

As shown in FIG. 1, the semiconductor die 1 comprises an integrated circuit region 10 and a die damage ring 20 extending along a perimeter of the integrated circuit region 10. The die damage ring 20 may have a rectangular shape and may extend along four edges E1-E4 of the semiconductor die 1. The die damage ring 20 may comprise a first terminal T1, a second terminal T2, an optional electro-static discharge (ESD) units ED disposed near the first terminal T1, and multiple damage detection elements DE1-DE4. According to an embodiment of the invention, the damage detection elements DE1-DE4 may comprise diodes, resistors, capacitors, invertors, or flip-flops, but not limited thereto. It is understood that the number and arrangement of the multiple damage detection elements in FIG. 1 are for illustration purposes only.

According to an embodiment of the invention, the first terminal T1 may be an input port that may be used to provide a test signal to the die damage ring 20. According to an embodiment of the invention, the second terminal T2 may be an output port that may be coupled to ground. The test results may be obtained at the second terminal T2. The ESD units ED provides protection to the multiple damage detection elements DE1-DE4. According to an embodiment of the invention, the first terminal T1 and/or the second terminal T2 may be used as a connection point/pad to a die damage ring of another integrated circuit die.

As shown in FIG. 2 and FIG. 3, the semiconductor die 1 includes a substrate 100 having the integrated circuit region 10 thereon. According to an embodiment of the invention, for example, the substrate 100 may be a semiconductor substrate. For example, the substrate 100 may be a silicon substrate, but is not limited thereto. According to an embodiment of the invention, a front end of line (FEOL) portion 110 is disposed on a front side S1 of the substrate 100. According to an embodiment of the invention, for example, the FEOL portion 110 may comprise active circuit elements 112 including, but not limited to, transistors.

According to an embodiment of the invention, a back end of line (BEOL) portion 120 is disposed on the FEOL portion 110. According to an embodiment of the invention, for example, the

BEOL portion 120 comprises a plurality of dielectric layers and a plurality of interconnect layers. The BEOL portion 120 includes a first discontinuous ring 21 disposed along the perimeter of the integrated circuit region 10. According to some embodiments, the first discontinuous ring 21 comprises a plurality of first interconnect blocks, for example, first interconnect blocks 211, 212 and 213, arranged intermittently along the perimeter of the integrated circuit region 10. According to some embodiments, the first interconnect blocks 211, 212 and 213 may be duplicate interconnect structures arranged at regular intervals along the perimeter of the integrated circuit region 10.

According to an embodiment of the invention, a power delivery network (PDN) portion 200 is disposed on a back side S2 of the substrate 100. As can be best seen in FIG. 3, a plurality of through substrate vias 310 is disposed along a perimeter of the integrated circuit region 10. The through substrate vias 310 penetrate through the substrate 100, the FEOL portion 110, the BEOL portion 120, and the PDN portion 200. The PDN portion 200 includes a second discontinuous ring 22 disposed along the perimeter of the integrated circuit region 10. According to an embodiment of the invention, the second discontinuous ring 22 comprises a plurality of second interconnect blocks, for example, the second interconnect blocks 221 and 222 arranged intermittently along the perimeter of the integrated circuit region 10. According to an embodiment of the invention, the second interconnect blocks 221 and 222 may be duplicate interconnect structures arranged at regular intervals along the perimeter of the integrated circuit region 10. According to an embodiment of the invention, the first interconnect blocks 211-213 and the second interconnect blocks 221-222 are arranged alternately along the perimeter of the integrated circuit region 10.

According to an embodiment of the invention, the first discontinuous ring 21 is interlaced with the second discontinuous ring 22 through the through substrate vias 310, thereby constituting the die damage ring 20. According to an embodiment of the invention, the first interconnect blocks 211-213 comprise top metal layers MT, and the through substrate vias 310 are directly connected to the top metal layers MT, respectively.

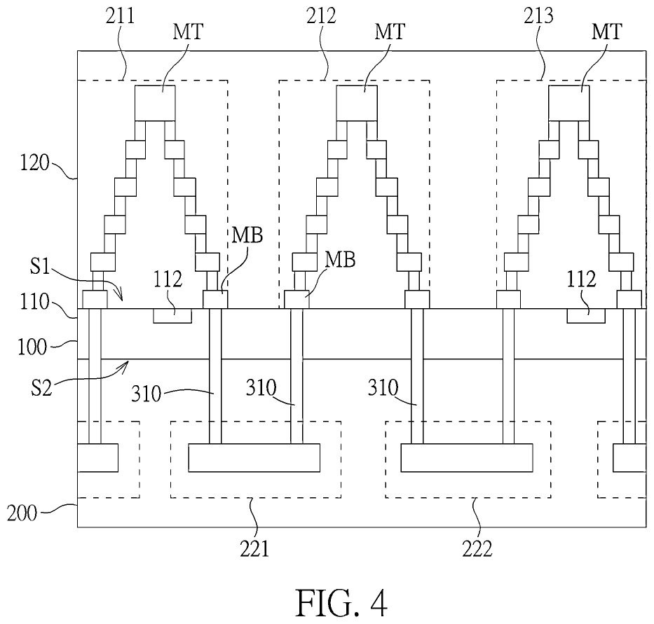

Please refer to FIG. 2 and FIG. 4. FIG. 4 is an enlarged, schematic diagram showing a portion of the die damage ring in FIG. 2 according to another embodiment of the invention, wherein like regions, layers or elements are designated by like numeral numbers or labels. As shown in FIG. 2 and FIG. 4, likewise, the FEOL portion 110 is disposed on the front side S1 of the substrate 100. According to an embodiment of the invention, for example, the FEOL portion 110 may comprise active circuit elements 112 including, but not limited to, transistors. According to an embodiment of the invention, the BEOL portion 120 is disposed on the FEOL portion 110. According to an embodiment of the invention, for example, the BEOL portion 120 comprises a plurality of dielectric layers and a plurality of interconnect layers. As can be best seen in FIG. 2, the BEOL portion 120 includes a first discontinuous ring 21 disposed along the perimeter of the integrated circuit region 10.

According to some embodiments, the first discontinuous ring 21 comprises a plurality of first interconnect blocks, for example, first interconnect blocks 211, 212 and 213, arranged intermittently along the perimeter of the integrated circuit region 10. According to some embodiments, the first interconnect blocks 211, 212 and 213 may be duplicate interconnect structures arranged at regular intervals along the perimeter of the integrated circuit region 10.

According to an embodiment of the invention, likewise, the PDN portion 200 is disposed on the back side S2 of the substrate 100. As can be best seen in FIG. 4, through substrate vias 310 are disposed along a perimeter of the integrated circuit region 10. According to an embodiment of the invention, the through substrate vias 310 penetrate through the substrate 100, the FEOL portion 110, and the PDN portion 200.

According to an embodiment of the invention, likewise, the PDN portion 200 includes a second discontinuous ring 22 disposed along the perimeter of the integrated circuit region 10. According to an embodiment of the invention, the second discontinuous ring 22 comprises a plurality of second interconnect blocks, for example, the second interconnect blocks 221 and 222 arranged intermittently along the perimeter of the integrated circuit region 10. According to an embodiment of the invention, the second interconnect blocks 221 and 222 may be duplicate interconnect structures arranged at regular intervals along the perimeter of the integrated circuit region 10. According to an embodiment of the invention, the first interconnect blocks 211-213 and the second interconnect blocks 221-222 are arranged alternately along the perimeter of the integrated circuit region 10.

According to an embodiment of the invention, the first discontinuous ring 21 is interlaced with the second discontinuous ring 22 through the through substrate vias 310, thereby constituting the die damage ring 20. According to an embodiment of the invention, the first interconnect blocks 211-213 comprise bottom metal layers MB, and the through substrate vias 310 are directly connected to the bottom metal layers MB, respectively.

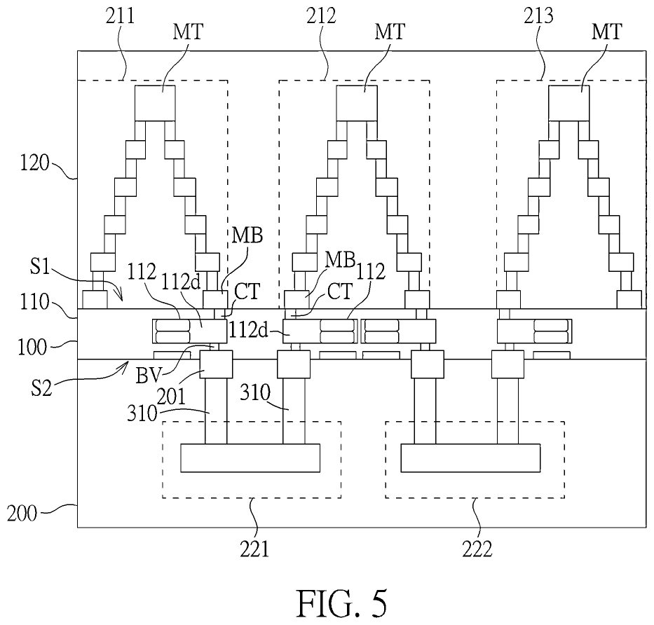

Please refer to FIG. 2 and FIG. 5. FIG. 5 is an enlarged, schematic diagram showing a portion of the die damage ring in FIG. 2 according to still another embodiment of the invention, wherein like regions, layers or elements are designated by like numeral numbers or labels. As shown in FIG. 2 and FIG. 5, likewise, the FEOL portion 110 is disposed on the front side S1 of the substrate 100. According to an embodiment of the invention, for example, the FEOL portion 110 may comprise active circuit elements 112 including, but not limited to, transistors. According to an embodiment of the invention, the BEOL portion 120 is disposed on the FEOL portion 110. According to an embodiment of the invention, for example, the BEOL portion 120 comprises a plurality of dielectric layers and a plurality of interconnect layers. As can be best seen in FIG. 2, the BEOL portion 120 includes a first discontinuous ring 21 disposed along the perimeter of the integrated circuit region 10.

According to some embodiments, the first discontinuous ring 21 comprises a plurality of first interconnect blocks, for example, first interconnect blocks 211, 212 and 213, arranged intermittently along the perimeter of the integrated circuit region 10. According to some embodiments, the first interconnect blocks 211, 212 and 213 may be duplicate interconnect structures arranged at regular intervals along the perimeter of the integrated circuit region 10.

According to an embodiment of the invention, likewise, the PDN portion 200 is disposed on the back side S2 of the substrate 100. The PDN portion 200 comprises buried rails 201, which are electrically connected to source/drain regions 112d of the active circuit elements 112, respectively, through buried vias BV. As can be best seen in FIG. 5, through substrate vias 310 are disposed along a perimeter of the integrated circuit region 10. According to an embodiment of the invention, the through substrate vias 310 penetrate through the substrate 100 and the PDN portion 200. The through substrate vias 310 are directly connected to the plurality of buried rails BV, respectively.

According to an embodiment of the invention, likewise, the PDN portion 200 includes a second discontinuous ring 22 disposed along the perimeter of the integrated circuit region 10. According to an embodiment of the invention, the second discontinuous ring 22 comprises a plurality of second interconnect blocks, for example, the second interconnect blocks 221 and 222 arranged intermittently along the perimeter of the integrated circuit region 10. According to an embodiment of the invention, the second interconnect blocks 221 and 222 may be duplicate interconnect structures arranged at regular intervals along the perimeter of the integrated circuit region 10. According to an embodiment of the invention, the first interconnect blocks 211-213 and the second interconnect blocks 221-222 are arranged alternately along the perimeter of the integrated circuit region 10.

According to an embodiment of the invention, the first discontinuous ring 21 is interlaced with the second discontinuous ring 22 through the through substrate vias 310 and the source/drain regions 112d of the active circuit elements 112, thereby constituting the die damage ring 20. According to an embodiment of the invention, the first interconnect blocks 211-213 comprise bottom metal layers MB, and the through substrate vias 310 are directly connected to the bottom metal layers MB, respectively. According to an embodiment of the invention, the bottom metal layers MB may be electrically connected to the source/drain regions 112d of the active circuit elements 112 through contacts CT.

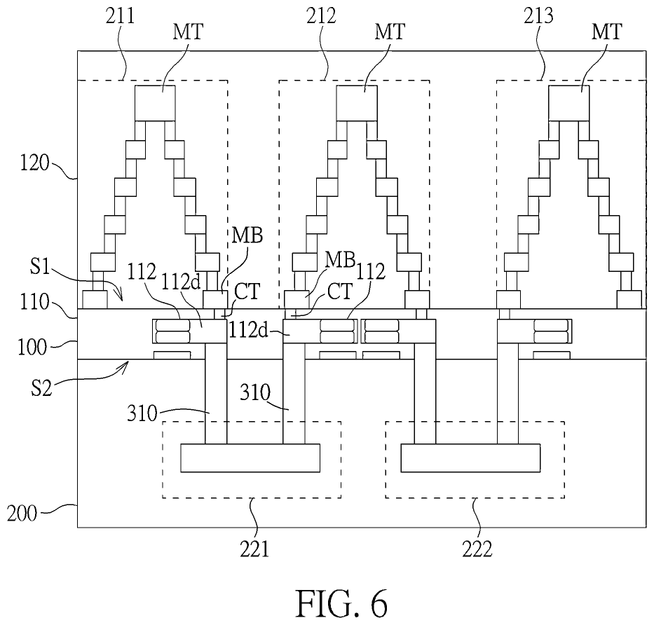

Please refer to FIG. 2 and FIG. 6. FIG. 6 is an enlarged, schematic diagram showing a portion of the die damage ring in FIG. 2 according to yet another embodiment of the invention, wherein like regions, layers or elements are designated by like numeral numbers or labels. As shown in FIG. 2 and FIG. 6, likewise, the FEOL portion 110 is disposed on the front side S1 of the substrate 100. According to an embodiment of the invention, for example, the FEOL portion 110 may comprise active circuit elements 112 including, but not limited to, transistors. According to an embodiment of the invention, the BEOL portion 120 is disposed on the FEOL portion 110. According to an embodiment of the invention, for example, the BEOL portion 120 comprises a plurality of dielectric layers and a plurality of interconnect layers. As can be best seen in FIG. 2, the BEOL portion 120 includes a first discontinuous ring 21 disposed along the perimeter of the integrated circuit region 10.

According to some embodiments, the first discontinuous ring 21 comprises a plurality of first interconnect blocks, for example, first interconnect blocks 211, 212 and 213, arranged intermittently along the perimeter of the integrated circuit region 10. According to some embodiments, the first interconnect blocks 211, 212 and 213 may be duplicate interconnect structures arranged at regular intervals along the perimeter of the integrated circuit region 10.

According to an embodiment of the invention, likewise, the PDN portion 200 is disposed on the back side S2 of the substrate 100. As can be best seen in FIG. 6, through substrate vias 310 are disposed along a perimeter of the integrated circuit region 10. According to an embodiment of the invention, the through substrate vias 310 penetrate through the substrate 100 and the PDN portion 200. The through substrate vias 310 are directly connected to the source/drain regions 112d of the active circuit elements 112, respectively.

According to an embodiment of the invention, likewise, the PDN portion 200 includes a second discontinuous ring 22 disposed along the perimeter of the integrated circuit region 10. According to an embodiment of the invention, the second discontinuous ring 22 comprises a plurality of second interconnect blocks, for example, the second interconnect blocks 221 and 222 arranged intermittently along the perimeter of the integrated circuit region 10. According to an embodiment of the invention, the second interconnect blocks 221 and 222 may be duplicate interconnect structures arranged at regular intervals along the perimeter of the integrated circuit region 10. According to an embodiment of the invention, the first interconnect blocks 211-213 and the second interconnect blocks 221-222 are arranged alternately along the perimeter of the integrated circuit region 10.

According to an embodiment of the invention, the first discontinuous ring 21 is interlaced with the second discontinuous ring 22 through the through substrate vias 310 and the source/drain regions 112d of the active circuit elements 112, thereby constituting the die damage ring 20. According to an embodiment of the invention, the first interconnect blocks 211-213 comprise bottom metal layers MB, and the through substrate vias 310 are directly connected to the bottom metal layers MB, respectively. According to an embodiment of the invention, the bottom metal layers MB may be electrically connected to the source/drain regions 112d of the active circuit elements 112 through contacts CT.

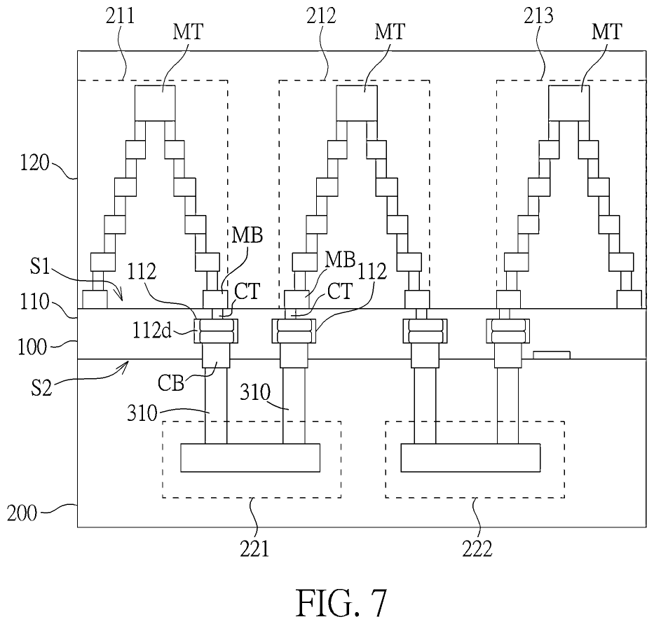

Please refer to FIG. 2 and FIG. 7. FIG. 7 is an enlarged, schematic diagram showing a portion of the die damage ring in FIG. 2 according to yet another embodiment of the invention, wherein like regions, layers or elements are designated by like numeral numbers or labels. As shown in FIG. 2 and FIG. 7, likewise, the FEOL portion 110 is disposed on the front side S1 of the substrate 100. According to an embodiment of the invention, for example, the FEOL portion 110 may comprise active circuit elements 112 including, but not limited to, transistors. According to an embodiment of the invention, the BEOL portion 120 is disposed on the FEOL portion 110. According to an embodiment of the invention, for example, the BEOL portion 120 comprises a plurality of dielectric layers and a plurality of interconnect layers. As can be best seen in FIG. 2, the BEOL portion 120 includes a first discontinuous ring 21 disposed along the perimeter of the integrated circuit region 10.

According to some embodiments, the first discontinuous ring 21 comprises a plurality of first interconnect blocks, for example, first interconnect blocks 211, 212 and 213, arranged intermittently along the perimeter of the integrated circuit region 10. According to some embodiments, the first interconnect blocks 211, 212 and 213 may be duplicate interconnect structures arranged at regular intervals along the perimeter of the integrated circuit region 10.

According to an embodiment of the invention, likewise, the PDN portion 200 is disposed on the back side S2 of the substrate 100. As can be best seen in FIG. 7, through substrate vias 310 are disposed along a perimeter of the integrated circuit region 10. According to an embodiment of the invention, the through substrate vias 310 penetrate through the substrate 100 and the PDN portion 200. The through substrate vias 310 are connected to the active circuit elements 112 through a plurality of backside contacts CB, respectively. The backside contacts CB are disposed at the back side S2 of the substrate 100.

According to an embodiment of the invention, likewise, the PDN portion 200 includes a second discontinuous ring 22 disposed along the perimeter of the integrated circuit region 10. According to an embodiment of the invention, the second discontinuous ring 22 comprises a plurality of second interconnect blocks, for example, the second interconnect blocks 221 and 222 arranged intermittently along the perimeter of the integrated circuit region 10. According to an embodiment of the invention, the second interconnect blocks 221 and 222 may be duplicate interconnect structures arranged at regular intervals along the perimeter of the integrated circuit region 10. According to an embodiment of the invention, the first interconnect blocks 211-213 and the second interconnect blocks 221-222 are arranged alternately along the perimeter of the integrated circuit region 10.

According to an embodiment of the invention, the first discontinuous ring 21 is interlaced with the second discontinuous ring 22 through the through substrate vias 310, the backside contacts CB, and the active circuit elements 112, thereby constituting the die damage ring 20. According to an embodiment of the invention, the first interconnect blocks 211-213 comprise bottom metal layers MB, and the through substrate vias 310 are directly connected to the bottom metal layers MB, respectively. According to an embodiment of the invention, the bottom metal layers MB may be electrically connected to the source/drain regions 112d of the active circuit elements 112 through contacts CT.

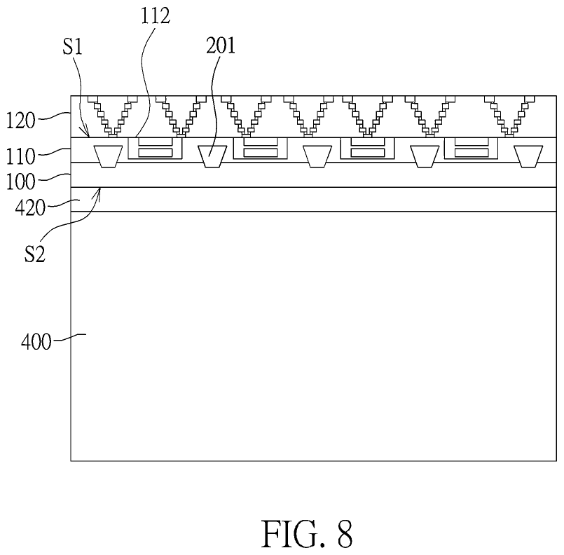

Please refer to FIG. 8 to FIG. 10. FIG. 8 to FIG. 10 are schematic diagrams showing an exemplary method for forming a semiconductor die according to one embodiment of the invention. As shown in FIG. 8, a substrate 100 is provided. For example, the substrate 100 may be a silicon substrate, but is not limited thereto. The substrate 100 has a front side S1 and a back side S2. The back side S2 of the substrate 100 may be adhered to a first carrier substrate 400. An etch stop layer 420 may be formed between the first carrier substrate 400 and the back side S2 of the substrate 100.

According to an embodiment of the invention, a front end of line (FEOL) portion 110 is formed on the front side S1 of the substrate 100. According to an embodiment of the invention, for example, the FEOL portion 110 may comprise active circuit elements 112 including, but not limited to, transistors. According to an embodiment of the invention, for example, buried power rails 201 may be formed in the substrate 100.

According to an embodiment of the invention, a back end of line (BEOL) portion 120 is formed on the FEOL portion 110. According to an embodiment of the invention, for example, the BEOL portion 120 comprises a plurality of dielectric layers and a plurality of interconnect layers. As previously described, the BEOL portion 120 includes a first discontinuous ring 21 disposed along the perimeter of an integrated circuit region 10, as depicted in FIG. 2. The first discontinuous ring 21 comprises a plurality of first interconnect blocks, for example, first interconnect blocks 211, 212 and 213, arranged intermittently along the perimeter of the integrated circuit region 10. The first interconnect blocks 211, 212 and 213 may be duplicate interconnect structures arranged at regular intervals along the perimeter of the integrated circuit region 10.

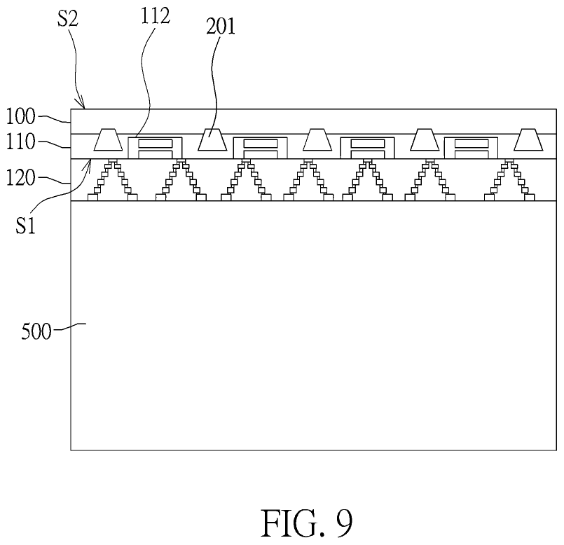

As shown in FIG. 9, the substrate 100 is then flipped and adhered to a second carrier substrate 500. Subsequently, the second carrier substrate 400 is removed by performing a grinding process and/or a chemical mechanical polishing (CMP) process. After the first carrier substrate 400 is removed, the etch stop layer 420 is then removed, thereby exposing the back side S2 of the substrate 100.

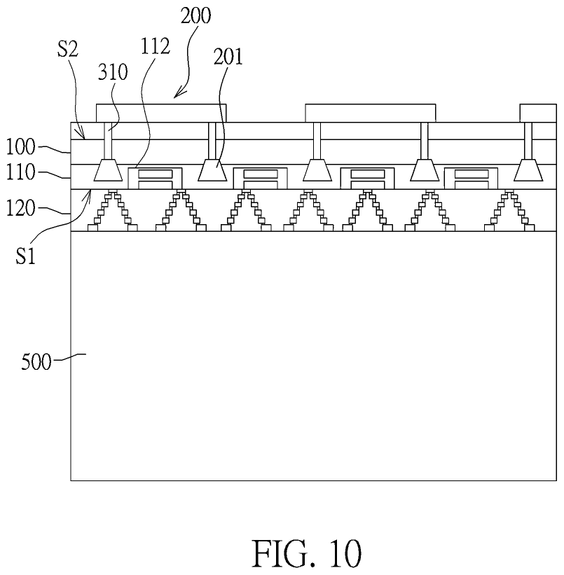

As shown in FIG. 10, a power delivery network (PDN) portion 200 is disposed on the back side S2 of the substrate 100. A plurality of through substrate vias 310 may be formed. The through substrate vias 310 penetrate through the substrate 100. The through substrate vias 310 may be electrically connected to the buried power rails 201. As previously described, the PDN portion 200 includes a second discontinuous ring 22 disposed along the perimeter of the integrated circuit region 10, as depicted in FIG. 2. According to an embodiment of the invention, the second discontinuous ring 22 comprises a plurality of second interconnect blocks, for example, the second interconnect blocks 221 and 222 arranged intermittently along the perimeter of the integrated circuit region 10. According to an embodiment of the invention, the second interconnect blocks 221 and 222 may be duplicate interconnect structures arranged at regular intervals along the perimeter of the integrated circuit region 10. According to an embodiment of the invention, the first interconnect blocks 211-213 and the second interconnect blocks 221-222 are arranged alternately along the perimeter of the integrated circuit region 10.

According to an embodiment of the invention, the first discontinuous ring 21 is interlaced with the second discontinuous ring 22 through the through substrate vias 310, thereby constituting the die damage ring 20 along the perimeter of the integrated circuit region 10.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor die, comprising:
a substrate comprising an integrated circuit region thereon;
a front end of line (FEOL) portion disposed on a front side of the substrate;
a back end of line (BEOL) portion disposed on the FEOL portion, wherein the BEOL portion comprises a first discontinuous ring disposed along a perimeter of the integrated circuit region;
a power delivery network (PDN) portion disposed on a back side of the substrate, wherein the PDN portion comprises a second discontinuous ring disposed along the perimeter of the integrated circuit region; and
a plurality of through substrate vias penetrating through the substrate and disposed along the perimeter of the integrated circuit region, wherein the first discontinuous ring is interlaced with the second discontinuous ring through the plurality of through substrate vias, thereby constituting a die damage ring.

2. The semiconductor die according to claim 1, wherein the first discontinuous ring comprises a plurality of first interconnect blocks arranged intermittently along the perimeter of the integrated circuit region.

3. The semiconductor die according to claim 2, wherein the plurality of first interconnect blocks comprises a plurality of duplicate first interconnect structures arranged at regular intervals along the perimeter of the integrated circuit region.

4. The semiconductor die according to claim 2, wherein the second discontinuous ring comprises a plurality of second interconnect blocks arranged intermittently along the perimeter of the integrated circuit region.

5. The semiconductor die according to claim 4, wherein the plurality of second interconnect blocks comprises a plurality of duplicate second interconnect structures arranged at regular intervals along the perimeter of the integrated circuit region.

6. The semiconductor die according to claim 4, wherein the plurality of first interconnect blocks and the plurality of second interconnect blocks are arranged alternately along the perimeter of the integrated circuit region.

7. The semiconductor die according to claim 2, wherein the plurality of first interconnect blocks comprises a plurality of top metal layers, and wherein the plurality of through substrate vias is directly connected to the plurality of top metal layers, respectively.

8. The semiconductor die according to claim 2, wherein the plurality of first interconnect blocks comprises a plurality of bottom metal layers, and wherein the plurality of through substrate vias is directly connected to the plurality of bottom metal layers, respectively.

9. The semiconductor die according to claim 1, wherein the PDN portion comprises a plurality of buried rails, and wherein the plurality of through substrate vias is directly connected to the plurality of buried rails, respectively.

10. The semiconductor die according to claim 1, wherein the front end of line (FEOL) portion comprises a plurality of active circuit elements.

11. The semiconductor die according to claim 10, wherein the plurality of active circuit elements comprises a plurality of source/drain regions, and wherein the plurality of through substrate vias is directly connected to the plurality of source/drain regions, respectively.

12. The semiconductor die according to claim 10, wherein a plurality of backside contacts is connected to the plurality of active circuit elements, respectively, and wherein the plurality of through substrate vias is directly connected to the plurality of backside contacts, respectively.

13. A method for forming a semiconductor die, comprising:
providing a substrate comprising an integrated circuit region thereon;
forming a front end of line (FEOL) portion on a front side of the substrate;
forming a back end of line (BEOL) portion on the FEOL portion, wherein the BEOL portion comprises a first discontinuous ring disposed along a perimeter of the integrated circuit region;
forming a power delivery network (PDN) portion on a back side of the substrate, wherein the PDN portion comprises a second discontinuous ring disposed along the perimeter of the integrated circuit region; and
forming a plurality of through substrate vias penetrating through the substrate and disposed along the perimeter of the integrated circuit region, wherein the first discontinuous ring is interlaced with the second discontinuous ring through the plurality of through substrate vias, thereby constituting a die damage ring.

14. The method according to claim 13, wherein the first discontinuous ring comprises a plurality of first interconnect blocks arranged intermittently along the perimeter of the integrated circuit region.

15. The method according to claim 14, wherein the plurality of first interconnect blocks comprises a plurality of duplicate first interconnect structures arranged at regular intervals along the perimeter of the integrated circuit region.

16. The method according to claim 14, wherein the second discontinuous ring comprises a plurality of second interconnect blocks arranged intermittently along the perimeter of the integrated circuit region.

17. The method according to claim 16, wherein the plurality of second interconnect blocks comprises a plurality of duplicate second interconnect structures arranged at regular intervals along the perimeter of the integrated circuit region.

18. The method according to claim 16, wherein the plurality of first interconnect blocks and the plurality of second interconnect blocks are arranged alternately along the perimeter of the integrated circuit region.

19. The method according to claim 14, wherein the plurality of first interconnect blocks comprises a plurality of top metal layers, and wherein the plurality of through substrate vias is directly connected to the plurality of top metal layers, respectively.

20. The method according to claim 14, wherein the plurality of first interconnect blocks comprises a plurality of bottom metal layers, and wherein the plurality of through substrate vias is directly connected to the plurality of bottom metal layers, respectively.

21. The method according to claim 13, wherein the PDN portion comprises a plurality of buried rails, and wherein the plurality of through substrate vias is directly connected to the plurality of buried rails, respectively.

22. The method according to claim 13, wherein the front end of line (FEOL) portion comprises a plurality of active circuit elements.

23. The method according to claim 22, wherein the plurality of active circuit elements comprises a plurality of source/drain regions, and wherein the plurality of through substrate vias is directly connected to the plurality of source/drain regions, respectively.

24. The method according to claim 22, wherein a plurality of backside contacts is connected to the plurality of active circuit elements, respectively, and wherein the plurality of through substrate vias is directly connected to the plurality of backside contacts, respectively.
